(19) United States
(12) Patent Application Publication
(10) Pub. No.: US 2025/0158594 A1
(43) Pub. Date: May 15, 2025

(54) BULK ACOUSTIC RESONATOR DEVICE WITH ENHANCED POWER HANDLING CAPABILITIES BY DOUBLE LAYER PIEZOELECTRIC MATERIAL

(71) Applicant: Huawei Technologies co., Ltd., Shenzhen (CN)

(72) Inventor: Ventsislav Yantchev, Helsinki (FI)

(21) Appl. No.: 19/023,847

(22) Filed: Jan. 16, 2025

Related U.S. Application Data
(63) Continuation of application No. PCT/EP2022/072463, filed on Aug. 10, 2022.

(51) Int. Cl. H03H 9/17; H03H 9/02

(52) U.S. Cl. CPC H03H 9/175; H03H 9/02015

(57) ABSTRACT

Embodiments of the invention relate to an acoustic resonator device for excitation of bulk acoustic waves (BAW) with enhanced power handling capabilities. The acoustic resonator device has a composite piezoelectrical platelet which comprises a first piezoelectrical layer and a second piezoelectric layer with the same or similar acoustic impedance but with opposite phase wave excitation for a given wave polarization. The dimensions of the composite piezoelectrical platelet for a given static capacitance can hence be increased, while maintaining a wide bandwidth of the acoustic resonator device.

### CROSS-REFERENCE TO RELATED APPLICATIONS

This application is a continuation of International Application No. PCT/EP2022/072463, filed on Aug. 10, 2022, the disclosure of which is hereby incorporated by reference in its entirety.

### TECHNICAL FIELD

Embodiments of the invention relate to an acoustic resonator device for excitation of bulk acoustic waves (BAW) with enhanced power handling capabilities.

### BACKGROUND

A BAW resonator is an electromechanical device in which a standing acoustic wave is generated by an electrical signal in a piezoelectric material between two metallic electrodes. BAW resonators can for example be used as radio frequency (RF) filters or duplexers and are on their way to replace conventional RF filters in many wireless communication applications.

There are two main types of BAW resonators, i.e., thin film bulk acoustic resonators (FBARs) and solidly mounted resonators (SMRs). A FBAR device includes a piezoelectric platelet sandwiched in between two electrodes. The resonance cavity in a FBAR is formed along the piezoelectric platelet and electrodes thickness. In an SMR device, additional layers are placed below the main structure of the device to serve as Bragg reflectors and provide structural support.

### SUMMARY

An objective of embodiments of the invention is to provide a solution which mitigates or solves the drawbacks and problems of conventional solutions.

Another objective of embodiments of the invention is to provide an acoustic resonator device with enhanced power handling capabilities.

The above and further objectives are solved by the subject matter of the independent claims. Further embodiments of the invention can be found in the dependent claims.

According to a first aspect of the invention, the above mentioned and other objectives are achieved with an acoustic resonator device comprising:
a first piezoelectrical layer and a second piezoelectric layer, wherein a bottom surface of the first piezoelectric layer is attached to a top surface of the second piezoelectric layer, wherein the first piezoelectrical layer and the second piezoelectric layer have a same or similar acoustic impedance, and wherein the first piezoelectrical layer and the second piezoelectric layer have opposite phase wave excitation for a given wave polarization; and
a first electrode attached to a top surface of the first piezoelectrical layer and a second electrode attached to a bottom surface of the second piezoelectric layer, wherein the first electrode and the second electrode are arranged to convert an electrical signal into an acoustic wave in the first piezoelectrical layer and the second piezoelectric layer.

An advantage of the acoustic resonator device according to the first aspect is that the disclosed acoustic resonator device enables the efficient excitation of the second thickness plate resonance in the first and second piezoelectric layers. Further, the acoustic resonator device can be optimized such that the interface between the first and second piezoelectric layers appears in the low stress region for the standing acoustic wave at resonance in view of achieving high Q factors.

In an implementation form of an acoustic resonator device according to the first aspect, a ratio between the acoustic impedance of the first piezoelectrical layer and the acoustic impedance of the second piezoelectrical layer is in the range of 0.8-1.2.

An advantage with this implementation form is that the elastic energy at resonance is evenly distributed along the first and second piezoelectric layers, thus promoting an efficient wave excitation in each piezoelectric layer.

In an implementation form of an acoustic resonator device according to the first aspect, a thickness d1 of the first piezoelectrical layer and a thickness d2 of the second piezoelectric layer are in a range of 0.3λ-0.7λ, where λ is the acoustic wavelength at resonance.

An advantage with this implementation form is that it enables that the second thickness resonance in the acoustic resonator device in a way that roughly half of a wavelength is above the interface between the piezoelectric layers, while the other half of a wavelength is below the interface, thus enhancing the excitation efficiency.

In an implementation form of an acoustic resonator device according to the first aspect, the thickness di of the first piezoelectrical layer and the thickness d2 of the second piezoelectric layer are in the range of 100-1100 nm.

An advantage with this implementation form is that these layer thicknesses enable the design of the acoustic resonator device operating in the desired frequency band.

In an implementation form of an acoustic resonator device according to the first aspect, the acoustic resonator device is configured to operate in a frequency range of 3-10 GHz.

An advantage with this implementation form is that bulk wave resonators are specifically needed in this frequency range. The frequencies bellow 3 GHz are using surface acoustic wave resonators or bulk wave resonators employing a single piezoelectric plate. Above the 10 GHz frequencies the required piezoelectric thicknesses for high-coupling resonators are not technologically feasible.

In an implementation form of an acoustic resonator device according to the first aspect, the acoustic resonator device is configured to operate at its second composite plate thickness resonance.

An advantage with this implementation form is that the acoustic resonator device is roughly twice thicker for the same resonance frequency as compared to a single piezoelectric layer resonator operating on the fundamental thickness resonance according to conventional solutions. This in turn requires roughly twice larger area to achieve the same static capacitance as compared to its single piezo layer counterpart. Accordingly, the volume of the two piezoelectric layer acoustic resonator device herein disclosed scales roughly by 4 times, which is associated with about the same downscaling in power density and respective improvement in power handling capabilities. Further, as the electrode between the first and second piezoelectric layers is eliminated the overall volume increase is typically larger than 4.

In an implementation form of an acoustic resonator device according to the first aspect, at least one of the first piezoelectrical layer and the second piezoelectric layer is from a 3 m point group.

An advantage with this implementation form is that high electromechanical coupling materials such as LiTaO₃ and LiNbO₃ can be used to excite either shear or longitudinally polarized waves with large electromechanical couplings.

In an implementation form of an acoustic resonator device according to the first aspect,
the first piezoelectrical layer is a compression negative C-axis AlScN layer and the second piezoelectric layer is a LiNbO₃ layer having a rotated Y-cut in the range of −134° to −154°, or vice versa; or
the first piezoelectrical layer is a compression positive C-axis AlScN layer and the second piezoelectric layer is a LiNbO₃ layer having a rotated Y-cut in the range of 26° to 46°, or vice versa.

An advantage with this implementation form is that both the first and second piezoelectrical layers support primarily the excitation of high coupling longitudinally polarized acoustic waves propagating along the plate thicknesses. The acoustic wavelength in AlScN is significantly larger than the wavelength in LiNbO₃, which results in thicker resonator stack for improved power handling. Further, AlScN is a material with excellent thermal conductivity unlike LiNbO₃.

In an implementation form of an acoustic resonator device according to the first aspect, the compression positive C-axis AlScN layer and the compression negative C-axis AlScN layer are an Al₁₋ₓScₓN layer, where x>0.2.

An advantage with this implementation form is that Sc concentration larger than 20% is needed to reach strong electromechanical coupling, i.e., of about 20% or larger, of the longitudinal bulk acoustic wave propagating along the C-axis.

In an implementation form of an acoustic resonator device according to the first aspect, the AlScN layer is grown on the LiNbO₃ layer, and wherein the LiNbO₃ layer is a single crystalline layer.

An advantage with this implementation form is that it applies a commercially viable technology. Further, the use of acoustically thin seed layer over LiNbO₃ is also envisaged to facilitate the c-axis growth of the AlScN.

In an implementation form of an acoustic resonator device according to the first aspect, the first piezoelectrical layer is a first LiNbO₃ layer and the second piezoelectric layer is a second LiNbO₃ layer, or vice versa, wherein the first LiNbO₃ layer and the second LiNbO₃ layer have a rotated Y-cut in any of the ranges of 153° to 173° or −7° to −27°, and wherein the first LiNbO₃ layer has a 180° rotated X-axis in relation to a X-axis of the second LiNbO₃ layer.

An advantage with this implementation form is that these cuts of LiNbO₃ are promoting specifically an efficient excitation of bulk acoustic wave with shear polarization, while the longitudinal bulk acoustic waves have suppressed electromechanical coupling. Further, the phase of excitation for the shear wave in the first piezoelectric layer is opposite to the phase of excitation in the second piezoelectric layer, while the phases of excitation of the longitudinal wave remains the same in both the first and second piezoelectric layers.

In an implementation form of an acoustic resonator device according to the first aspect, the first piezoelectrical layer is a first LiNbO₃ layer having a first rotated Y-cut and the second piezoelectric layer is a second LiNbO₃ layer having a second rotated Y-cut, or vice versa, wherein the first rotated Y-cut is rotated 180° around an X-axis of the LiNbO₃ layer crystal in relation to the second rotated Y-cut, or vice versa.

In an implementation form of an acoustic resonator device according to the first aspect, the first LiNbO₃ layer has a rotated Y-cut in the range of 26° to 46° and the second LiNbO₃ layer has a rotated Y-cut in the range of −134° to −154°.

An advantage with this implementation form is that these cuts of LiNbO₃ are promoting specifically an efficient excitation of bulk acoustic wave with longitudinal polarization, while the shear bulk acoustic waves have suppressed electromechanical coupling.

In an implementation form of an acoustic resonator device according to the first aspect, the first LiNbO₃ layer has a rotated Y-cut in the range of 153° to 173° and the second LiNbO₃ layer has a rotated Y-cut in the range of −7° to −27°.

An advantage with this implementation form is that these cuts of LiNbO₃ are promoting specifically an efficient excitation of bulk acoustic wave with shear polarization, while the longitudinal bulk acoustic waves have suppressed electromechanical coupling.

In an implementation form of an acoustic resonator device according to the first aspect, the first LiNbO₃ layer has a 0°, 60°, 90°, 120° or 180° rotated X-axis in relation to the X-axis of the second LiNbO₃ layer.

An advantage with this implementation form is that it distorts polarization and excitation phase of the shear wave between the first and second piezoelectric layers and thus suppress the shear wave excitation efficiency. The implementation is specifically valuable for resonators meant to operate with longitudinal waves.

In an implementation form of an acoustic resonator device according to the first aspect, the first LiNbO₃ layer and the second LiNbO₃ layer are single crystalline layers.

An advantage with this implementation form is that the mechanical quality factor of single crystalline layers is better than that of polycrystalline layers. Typically, single crystal materials demonstrate better power handling abilities as compared to their polycrystalline counterparts.

In an implementation form of an acoustic resonator device according to the first aspect, the first LiNbO₃ layer is attached to the second LiNbO₃ layer, or vice versa, by bonding.

In an implementation form of an acoustic resonator device according to the first aspect, the second piezoelectric layer is acoustically coupled to a Bragg-mirror, wherein the Bragg-mirror comprises a plurality of alternating layers having different acoustic impedances.

In an implementation form of an acoustic resonator device according to the first aspect, the plurality of alternating layers are arranged on, and acoustically coupled to a supporting substrate.

Further applications and advantages of embodiments of the invention will be apparent from the following detailed description.

### BRIEF DESCRIPTION OF THE DRAWINGS

The appended drawings are intended to clarify and explain different embodiments of the invention, in which:

FIG. 1 shows an acoustic resonator device according to an embodiment of the invention;

FIG. 2 shows an acoustic resonator device according to another embodiment of the invention;

FIGS. 3a-3b show a first piezoelectrical layer and a second piezoelectrical layer according to embodiments of the invention;

FIG. 4 shows a first piezoelectrical layer and a second piezoelectrical layer according to embodiments of the invention;

FIGS. 5a-5b show a first piezoelectrical layer and a second piezoelectrical layer according to embodiments of the invention; and

FIGS. 6-8 show performance results.

### DETAILED DESCRIPTION OF THE EMBODIMENTS

BAW resonators in the 3 GHz-10 GHz frequency range requires wide bandwidths and low resonator capacitances. For example, sub 6 GHz acoustic resonators requires bandwidths (BW) of around 10% and resonator capacitances C of about 1 pF and bellow for good performance.

In BAW resonators, the static capacitance Co per unit electrode area increases with frequency scaling as the thickness of the piezoelectric layer reduces, while resonance frequency increases. For example: a Lithium Niobate (LiNbO₃) membrane for fundamental acoustic resonance in the 4 GHz range is expected to have 565-1130 μm² area to reach static capacitance in the range of 1 pF, depending on the excitation mode. This results in small area electrodes of about 23 um×23 um to 33 um×33 um and even smaller for FBARs with a capacitance C bellow 1 pF. Such a small resonator limits the power handling and experience poorer energy confinement.

To improve the power handling capabilities of BAW resonators, a new composite piezoelectric platelet for efficient excitation of BAWs is disclosed. The proposed composite piezoelectric platelet comprises two piezoelectrical layers and may be used as building blocks in FBAR devices and SMR devices where it increases both the area and the thickness of the FBAR or SMR platelet, respectively, for a given static capacitance Co. The energy density in the resonator is thereby decreased, allowing the power handling capabilities of the resonator to be improved compared to conventional solutions.

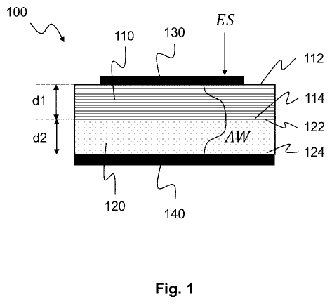

Thus, FIG. 1 shows an acoustic resonator device 100 according to an embodiment of the invention. The acoustic resonator device 100 may be configured to operate in a frequency range of 3-10 GHz but is not limited thereto and may be a FBAR device or a SMR device, or be part of a FBAR device or a SMR device. With reference to FIG. 1, the acoustic resonator device 100 comprises a first piezoelectrical layer 110 and a second piezoelectric layer 120, respectively. A bottom surface 114 of the first piezoelectric layer 110 is attached to a top surface 122 of the second piezoelectric layer 120. The acoustic resonator device 100 further comprises a first electrode 130 attached to a top surface 112 of the first piezoelectrical layer 110 and a second electrode 140 attached to a bottom surface 124 of the second piezoelectric layer 120. The first electrode 130 and the second electrode 140 are arranged to convert an electrical signal ES into an acoustic wave AW in the first piezoelectrical layer 110 and the second piezoelectric layer 120. Thus, the acoustic wave AW is generated in both the first piezoelectrical layer 110 and the second piezoelectric layer 120.

The first piezoelectrical layer 110 and the second piezoelectric layer 120 have a same or similar acoustic impedance. In embodiments, a ratio between the acoustic impedance of the first piezoelectrical layer 110 and the acoustic impedance of the second piezoelectrical layer 120 is in the range of 0.8-1.2. Thus, an even energy distribution between the first 110 and second 120 piezoelectric layers can be achieved. The first piezoelectrical layer 110 and the second piezoelectric layer 120 further have opposite phase wave excitation for a given wave polarization. The given wave polarizations may be of the type longitudinal or shear with respect to wave propagation. One given wave polarization at a time, i.e., either longitudinal or shear, is of interest and the other should be sufficiently suppressed.

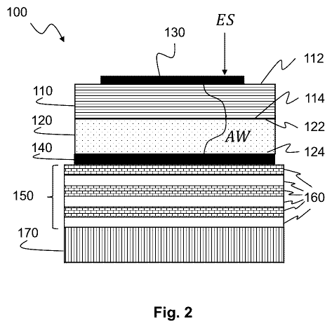

FIG. 2 shows the acoustic resonator device 100 according to an embodiment of the invention where the acoustic resonator device 100 is implemented as a SMR device or as part of a SMR device. The acoustic resonator device 100 may be configured to operate in the frequency range of 3-10 GHz. In addition to the parts described with reference to FIG. 1, the acoustic resonator device 100 according to the embodiment shown in FIG. 2 comprises a Bragg-mirror 150 and a supporting substrate 170 below the Bragg-mirror. With reference to FIG. 2, the second piezoelectric layer 120 is acoustically coupled to the Bragg-mirror 150. The term acoustically coupled may be understood as a direct connection between the piezoelectric layer and the Bragg mirror when the electrode is considered included in the first layer of the Bragg mirror, such as if the Bragg mirror start with a tungsten (W) layer or a Molybdenum (Mo) layer, etc. It is also possible to have acoustically coupling through the electrode, e.g., when the electrode is not considered part of the Bragg Mirror such as using an acoustically thin Al electrode, etc. The Bragg-mirror 150 comprises a plurality of alternating layers 160 having different acoustic impedances. The plurality of alternating layers 160 are in turn arranged on, and acoustically coupled to the supporting substrate 170. Each layer of the Bragg mirror may be about quarter wavelength thick, and the reflectivity from each layer will be larger if the difference between the acoustic impedances of the layers is larger. Typical materials with large acoustic impedance differences may be used such as W/SiO₂, Mo/SiO₂, and SiN/SiO₂.

The acoustic resonator device 100 according to any of the herein described embodiments may be configured to operate at its second composite plate thickness resonance. The second plate thickness resonance can be defined as the resonance at which the acoustic wave AW forms a 1λ standing wave along the thickness of the acoustic resonator device 100. The mentioned thickness may be defined as the sum of all layers of the acoustic resonator device 100 including the electrodes. To enable the acoustic resonator device 100 to operate at its second composite plate thickness resonance, a thickness di of the first piezoelectrical layer 110 and a thickness d2 of the second piezoelectric layer 120 (see FIG. 1) may be selected such that the thickness of the acoustic resonator device 100 corresponds to an acoustic wavelength λ at resonance. Each piezoelectrical layer 110, 120 may e.g., be approximately half an acoustic wavelength λ/2 thick. In embodiments, the thickness di of the first piezoelectrical layer 110 and the thickness d2 of the second piezoelectric layer 120 are in a range of 0.3λ-0.7λ, where λ is the acoustic wavelength at resonance in each material. Furthermore, the thickness di of the first piezoelectrical layer 110 and the thickness d2 of the second piezoelectric layer 120 may be in the range of 100-1100 nm since this is technically feasible and can also define the resonance in a desired frequency range. The thickness d1 and d2 may be considered as design parameters and may depend on asymmetry of the electrodes (different materials, different thickness, etc.) as well as for tuning the coupling when the piezoelectric materials have different acoustic impedance (i.e., different energy distribution).

The first piezoelectrical layer 110 and the second piezoelectric layer 120 may be selected from one or more crystal symmetry groups, i.e., the first piezoelectrical layer 110 and the second piezoelectric layer 120 may belong to the same or different crystal symmetry groups. In embodiments, at least one of the first piezoelectrical layer 110 and the second piezoelectric layer 120 is from a 3 m point group. The 3 m point group includes e.g., LiNbO₃ and Lithium Tantalate (LiTaO₃). If only one of the first piezoelectrical layer 110 and the second piezoelectric layer 120 is from the 3 m point group, the other one of the first piezoelectrical layer 110 and the second piezoelectric layer 120 may be from a 6 mm group including Aluminum Scandium Nitride (AlScN) and Sc doped AIN.

In embodiments where the first piezoelectrical layer 110 and the second piezoelectric layer 120 are from different crystal symmetry groups, the first piezoelectrical layer 110 may be a compression negative C-axis AlScN layer and the second piezoelectric layer 120 may be a LiNbO₃ layer having a rotated Y-cut in the range of −134° to −154°, or vice versa. The first piezoelectrical layer 110 may further be a compression positive C-axis AlScN layer and the second piezoelectric layer 120 may be a LiNbO₃ layer having a rotated Y-cut in the range of 26° to 46°, or vice versa. In this way, the first piezoelectrical layer 110 and the second piezoelectric layer 120 have different crystal orientation and combinations between compression positive and compression negative excitations in each layer is achieved. The compression positive C-axis AlScN layer and the compression negative C-axis AlScN layer may be an Al₍₁₋ₓ₎ScₓN layer, where x>0.2. 10. The AlScN layer may be grown on the LiNbO₃ layer, and the LiNbO₃ layer may be a single crystalline layer. The AlScN layer may e.g., be grown using a deposition or a spluttering technique on a single crystalline layer LiNbO₃ layer fabricated e.g., by means of piezoelectric on insulator (POI) techniques.

In embodiments, the first piezoelectrical layer 110 and the second piezoelectric layer 120 are both from the 3 m point group. For example, the first piezoelectrical layer 110 may be a first LiNbO₃ layer and the second piezoelectric layer 120 may be a second LiNbO₃ layer, or vice versa. The first LiNbO₃ layer and the second LiNbO₃ layer may have a rotated Y-cut in any of the ranges of 153° to 173° or −7° to −27°, and the first LiNbO₃ layer may have a 180° rotated X-axis in relation to an X-axis of the second LiNbO₃ layer. These configurations make the phase excitation in one of the piezoelectric layers opposite to the phase excitation in the other piezoelectric layer and is valid for shear wave polarization only hence the mentioned cuts.

Furthermore, the first piezoelectrical layer 110 may be a first LiNbO₃ layer having a first rotated Y-cut and the second piezoelectric layer 120 may be a second LiNbO₃ layer having a second rotated Y-cut, or vice versa, where the first rotated Y-cut is rotated 180° around an X-axis of the LiNbO₃ layer crystal in relation to the second rotated Y-cut, or vice versa. For example, the first LiNbO₃ layer may have a rotated Y-cut in the range of 26° to 46° and the second LiNbO₃ layer may have a rotated Y-cut in the range of −134° to −154°. Alternatively, the first LiNbO₃ layer may have a rotated Y-cut in the range of 153° to 173° and the second LiNbO₃ layer may have a rotated Y-cut in the range of −7° to −27°. The first LiNbO₃ layer may further have a 0°, 60°, 90°, 120° or 180° rotated X-axis in relation to the X-axis of the second LiNbO₃ layer. These configurations make the phases of excitation in the two piezoelectric layers opposite to each other for either the longitudinal wave, the shear wave or both. The electromechanical coupling will be strong for a desired wave polarization at its second thickness resonance while minimizing the coupling of the remaining polarizations.

The first LiNbO₃ layer and the second LiNbO₃ layer may be single crystalline layers and may e.g., be fabricated by means of ion-slicing techniques on carrier substrates such as POI substrates. The first LiNbO₃ layer may then be attached to the second LiNbO₃ layer, or vice versa, by bonding.

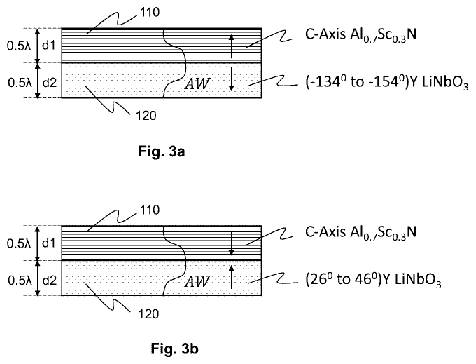

FIGS. 3-5 shows examples of the above-described embodiments of the first piezoelectrical layer 110 and the second piezoelectric layer 120. In the disclosed examples, the thickness d1 of the first piezoelectrical layer 110 and the thickness d2 of the second piezoelectric layer 120 are approximately half the acoustic wavelength 0.5λ at resonance. The acoustic resonator device 100 comprising the first piezoelectrical layer 110 and the second piezoelectric layer 120 may thereby operate at its second composite plate thickness resonance.

In FIG. 3a, the first piezoelectrical layer 110 is a compression negative C-axis Al_{0.7}Sc_{0.3}N layer and the second piezoelectric layer 120 is a LiNbO₃ layer having a rotated Y-cut in the range of −134° to −154°.

In FIG. 3b, the first piezoelectrical layer 110 is a compression positive C-axis Al_{0.7}Sc_{0.3}N layer and the second piezoelectric layer 120 is a LiNbO₃ layer having a rotated Y-cut in the range of −134° to −154°.

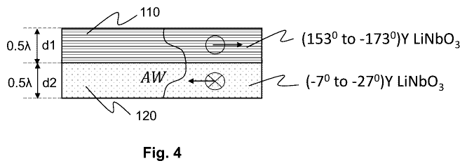

In FIG. 4, the first piezoelectrical layer 110 is a first LiNbO₃ layer have a rotated Y-cut in the ranges of 153° to 173° and the second piezoelectric layer 120 is a second LiNbO₃ layer having a rotated Y-cut in the ranges of −7° to −27°. The first LiNbO₃ layer has a 180° rotated X-axis in relation to an X-axis of the second LiNbO₃ layer.

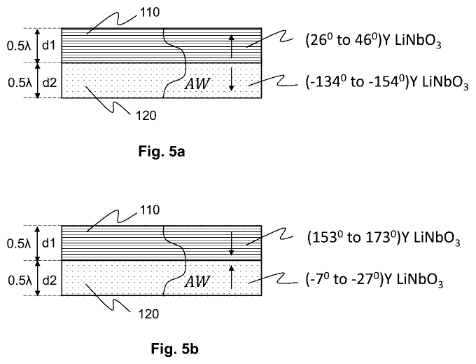

In FIG. 5a, the first piezoelectrical layer 110 is a first LiNbO₃ layer having a first rotated Y-cut in the range of 26° to 46° and the second piezoelectric layer 120 may be a second LiNbO₃ layer having a second rotated Y-cut in the range of −134° to −154°. The first LiNbO₃layer may further have a 0°, 60°, 90°, 120° or 180° rotated X-axis in relation to the X-axis of the second LiNbO₃ layer.

In FIG. 5b, the first piezoelectrical layer 110 is a first LiNbO₃ layer having a first rotated Y-cut in the range of 153° to 173° and the second piezoelectric layer 120 is a second LiNbO₃ layer having a second rotated Y-cut in the range of −7° to −27°. The first LiNbO₃ layer may further have a 0°, 60°, 90°, 120° or 180° rotated X-axis in relation to the X-axis of the second LiNbO₃ layer.

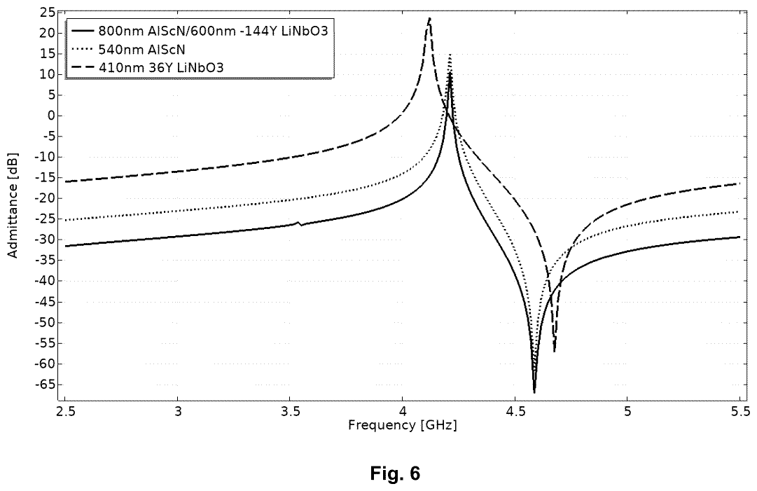

Moreover, FIGS. 6-8 show different performance results of an acoustic resonator device 100 according to embodiments of the invention. The absolute values of the admittance in dB as a function of the frequency are shown in FIGS. 6-8.

FIG. 6 shows a proposed c-AlScN/−144Y LiNbO₃ composite having the same BW as the high coupling c-AlScN (Kt2˜20%) single piezoelectric layer resonator, but its capacitance per area is 2.1 smaller as compared to the latter one. The composite acoustic resonator device 100 is 2.6 times ticker compared to the conventional c-AlScN based device resulting in 2.1*2.6=5.4 times decreased energy density per constant capacitance. Thus, the disclosed acoustic resonator device 100 can be used for enhanced power handling in wideband filters that usually use AlScN films. As compared to 36Y LiNbO₃ single piezo-layer device, the BW is compromised at the expense of 6 times smaller capacitance per unit area. The disclosed acoustic resonator device 100 is 3.4 times ticker compared to conventional devices resulting in 3.4*6=20.4 times lower energy density at constant capacitance. The AlScN further improve the heat dissipation abilities of the disclosed acoustic resonator device 100 as compared to 36Y LiNbO₃ single piezo-layer device.

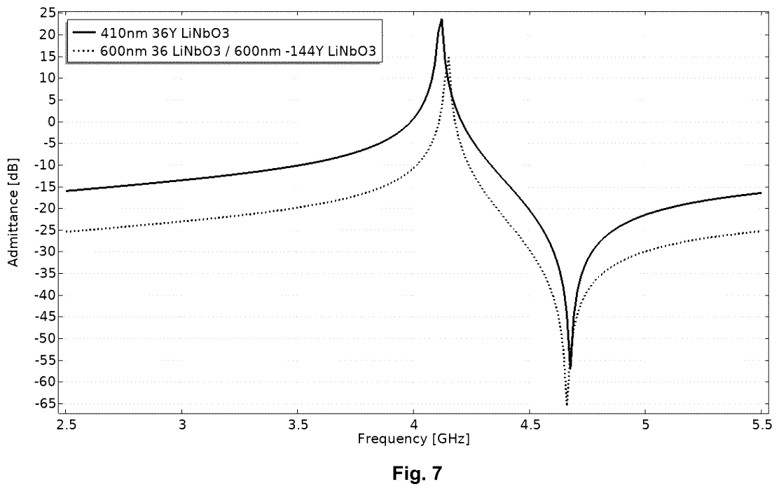

FIG. 7 shows a proposed 36Y LiNbO₃/−144Y LiNbO₃ composite having just a bit lower BW as compared to the classical single 36Y LiNbO₃ layer structure, while having 3 times smaller capacitance per unit area. The disclosed acoustic resonator device 100 is 2.9 times ticker compared to conventional single 36Y LiNbO₃ layer device resulting in 3*2.9=8.7 times decreased energy density per constant capacitance. The disclosed acoustic resonator device 100 can e.g., be used for enhanced power handling in wideband filters.

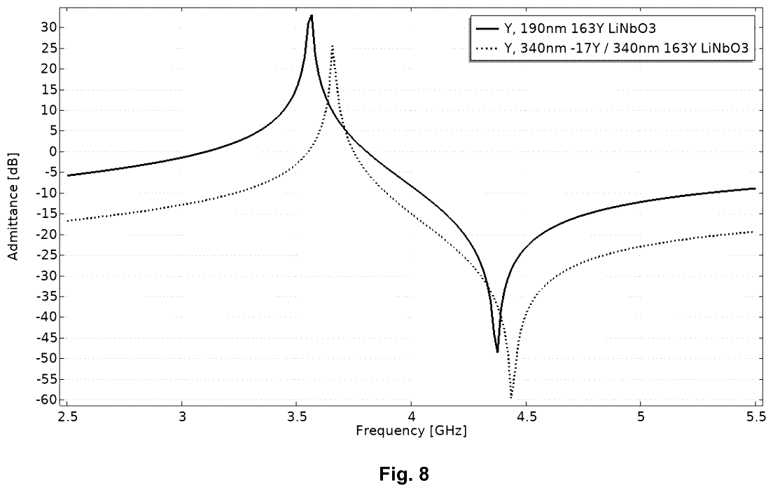

FIG. 8 shows a proposed −17Y LiNbO₃/163Y LiNbO₃ composite having just a bit lower BW as compared to the classical single 163Y LiNbO₃ layer structure, while having 3.55 times smaller capacitance per unit area. The disclosed acoustic resonator device 100 is 3.5 times ticker compared to conventional single 163Y LiNbO₃ layer device resulting in 3.55*3.5=12.4 times decreased energy density per constant capacitance. The disclosed acoustic resonator device 100 can e.g., be used for enhanced power handling in wideband filters.

Finally, it should be understood that the invention is not limited to the embodiments described above, but also relates to and incorporates all embodiments within the scope of the appended independent claims.

What is claimed:

1. An acoustic resonator device comprising:
a first piezoelectrical layer and a second piezoelectric layer, wherein a bottom surface of the first piezoelectric layer is attached to a top surface of the second piezoelectric layer, wherein the first piezoelectrical layer and the second piezoelectric layer have a same acoustic impedance, or the first piezoelectric layer and the second piezoelectric layer have acoustic impedances within a preset range of each other, and wherein the first piezoelectrical layer and the second piezoelectric layer have opposite phase wave excitation for a given wave polarization; and
a first electrode attached to a top surface of the first piezoelectrical layer and a second electrode attached to a bottom surface of the second piezoelectric layer, wherein the first electrode and the second electrode are arranged to convert an electrical signal (ES) into an acoustic wave (AW) in the first piezoelectrical layer and the second piezoelectric layer.

2. The acoustic resonator device according to claim 1, wherein a ratio between the acoustic impedance of the first piezoelectrical layer and the acoustic impedance of the second piezoelectrical layer is in the preset range of 0.8-1.2.

3. The acoustic resonator device according to claim 1, wherein a thickness di of the first piezoelectrical layer and a thickness d2 of the second piezoelectric layer are in a range of 0.3λ-0.7λ, where λ is an acoustic wavelength at resonance.

4. The acoustic resonator device according to claim 3, wherein the thickness di of the first piezoelectrical layer and the thickness d2 of the second piezoelectric layer are in a range of 100-1100 nm.

5. The acoustic resonator device according to claim 1, wherein the acoustic resonator device is configured to operate in a frequency range of 3-10 GHz.

6. The acoustic resonator device according to claim 1, wherein the acoustic resonator device is configured to operate at its second composite plate thickness resonance.

7. The acoustic resonator device according to claim 1, wherein at least one of the first piezoelectrical layer and the second piezoelectric layer is from a 3 m point group.

8. The acoustic resonator device according to claim 7, wherein:
the first piezoelectrical layer is a compression negative C-axis AlScN layer and the second piezoelectric layer is a LiNbO₃ layer having a rotated Y-cut in a range of −134° to −154°, or vice versa; or
the first piezoelectrical layer is a compression positive C-axis AlScN layer and the second piezoelectric layer is a LiNbO₃ layer having a rotated Y-cut in the range of 26° to 46°, or vice versa.

9. The acoustic resonator device according to claim 8, wherein the compression positive C-axis AlScN layer or the compression negative C-axis AlScN layer is an Al₍₁₋ₓ₎ScₓN layer, where x>0.2.

10. The acoustic resonator device according to claim 8, wherein the AlScN layer is grown on the LiNbO₃ layer, and wherein the LiNbO₃ layer is a single crystalline layer.

11. The acoustic resonator device according to claim 7, wherein the first piezoelectrical layer is a first LiNbO₃ layer and the second piezoelectric layer is a second LiNbO₃ layer, or vice versa, wherein the first LiNbO₃ layer and the second LiNbO₃ layer have a rotated Y-cut in any of the ranges of 153° to 173° or −7° to −27°, and wherein the first LiNbO₃ layer has a 180° rotated X-axis in relation to a X-axis of the second LiNbO₃ layer.

12. The acoustic resonator device according to claim 7, wherein the first piezoelectrical layer is a first LiNbO₃ layer having a first rotated Y-cut and the second piezoelectric layer is a second LiNbO₃ layer having a second rotated Y-cut, or vice versa, wherein the first rotated Y-cut is rotated 180° around an X-axis of the LiNbO₃ layer crystal in relation to the second rotated Y-cut, or vice versa.

13. The acoustic resonator device according to claim 12, wherein the first LiNbO₃ layer has a rotated Y-cut in a range of 26° to 46° and the second LiNbO₃ layer has a rotated Y-cut in a range of −134° to −154°.

14. The acoustic resonator device according to claim 12, wherein the first LiNbO₃ layer has a rotated Y-cut in s range of 153° to 173° and the second LiNbO₃ layer has a rotated Y-cut in a range of −7° to −27°.

15. The acoustic resonator device according to claim 13, wherein the first LiNbO₃ layer has a 0°, 60°, 90°, 120° or 180° rotated X-axis in relation to the X-axis of the second LiNbO₃ layer.

16. The acoustic resonator device according to claim 12, wherein the first LiNbO₃ layer and the second LiNbO₃ layer are single crystalline layers.

17. The acoustic resonator device according to claim 16, wherein the first LiNbO₃ layer is attached to the second LiNbO₃ layer, or vice versa, by bonding.

18. The acoustic resonator device according to claim 11, wherein the second piezoelectric layer is acoustically coupled to a Bragg-mirror, wherein the Bragg-mirror comprises a plurality of alternating layers having different acoustic impedances.

19. The acoustic resonator device according to claim 18, wherein the plurality of alternating layers are arranged on, and acoustically coupled to a supporting substrate.
